(19) United States
(12) Patent Application Publication
(10) Pub. No.: US 2011/0215194 A1
(43) Pub. Date: Sep. 8, 2011

(54) ELECTRONIC POWER MODULE FOR AN AIRCRAFT ACTUATOR

(75) Inventors: Mathieu CHARLAS, Tarbes (FR); Jean-Pierre HABAS, Montpellier Cedex 5 (FR); Valérie NASSIET, Tarbes (FR)

(73) Assignee: HISPANO SUIZA, Colombes Cedex (FR)

(21) Appl. No.: 13/037,671

(22) Filed: Mar. 1, 2011

(30) Foreign Application Priority Data
Mar. 3, 2010 (FR) 10 00866

(51) Int. Cl. B64C 13/24; B64C 13/00; H05K 7/00

(52) U.S. Cl. 244/99.2; 361/679.01

(57) ABSTRACT

An electronic power module, in particular an all-electric actuator for an aircraft, comprising a support having electronic components mounted thereon together with a package covering and surrounding the components and fastened on the support, the package having walls fastened on corresponding faces of an intermediate part that is fastened to the support inside the package.

The present invention relates to an electronic power module used in particular for implementing an all-electric actuator for use in aviation applications, in particular for mounting on a turbomachine such as a turbojet or a turboprop.

A power module conventionally comprises electronic components mounted on a metal-plated support, and a package covering and surrounding the electronic components.

In the prior art, the package is generally made of a polymer material and it is fastened to the support by adhesive at the ends of its side walls.

Nevertheless, fastening the package by adhesive is found not to be sufficiently reliable. During the various stages of flight of an aircraft, the power module is subjected to acceleration and to vibration, and the adhesive joints are subjected to traction forces that tend to separate the package from the support. In order to avoid that, it is known to add fastening by means of bolts between the package and the support. That solution is not satisfactory in aviation since it leads to increasing the overall weight of the power system, and it requires special zones to be formed for bolting the package and the support together.

A particular object of the invention is to provide a solution to the above-mentioned drawbacks that is simple, effective, and inexpensive.

To this end, the invention provides an electronic power module comprising a support having electronic components mounted thereon together with a package covering and surrounding the components and fastened on the support, the module being characterized in that the package has walls fastened on corresponding faces of an intermediate part that is fastened to the support inside the package, said walls of the package and the corresponding faces of the intermediate part being inclined obliquely on the support of the components.

Unlike the prior art, the package is no longer fastened directly to the support, but is fastened to an intermediate part that is itself fastened to the support.

The use of this intermediate part makes it possible to subject the junction between the package and the intermediate part to shear instead of subjecting the junction to traction. The fastening area between the package and the intermediate part is much greater than the area of adhesive between the package and the support, as used in the prior art. This guarantees a better lifetime for the module as assembled in this way, and without having recourse to the bolting elements.

Furthermore, it is possible to perform surface treatments on the intermediate part with fastening promoters, which treatments were not possible in the prior art when the package was fastened directly to a metal-plated support.

The walls of the package and the corresponding faces of the part may be parallel. They may also converge a little going away from the support, thus making it easier to position the package around the intermediate part.

The above-mentioned walls of the package and the corresponding faces of the part may be fastened to one another by a layer of adhesive.

The material selected for making the intermediate part may thus depend solely on the design constraints for the adhesive joint, thus making it possible to optimize conditions for fastening the package to the intermediate part.

The adhesive used may be a thixotropic adhesive, which is found to be particularly advantageous when the walls of the package and the faces of the intermediate part are inclined relative to the support, since the adhesive becomes spread out on the package being mounted around the intermediate part.

In another variant embodiment of the invention, the walls of the package and the corresponding faces of the part are applied against one another and are fastened together by laser welding through the walls of the package.

To this end, a laser beam is focused on the interface between the walls of the package and the corresponding faces of the intermediate part, thereby heating the faces of the intermediate part and causing a fine thickness of its material to melt, thus enabling the package to be secured to the intermediate part.

The intermediate part may be fastened to the support by various means, e.g. by soldering, welding, sintering, or laser welding.

The invention provides an all-electric actuator, of the kind used in avionics systems, and including an electronic power module of the above-described type.

The invention can be better understood and other details, advantages and characteristics of the invention appear on reading the following description made by way of nonlimiting example and with reference to the accompanying drawing, in which:

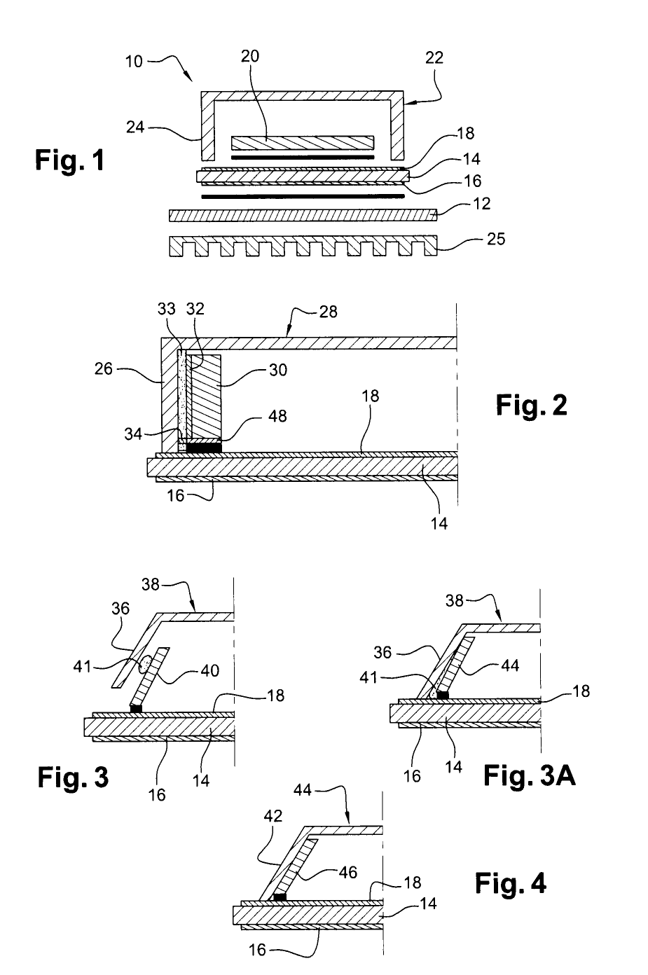

FIG. 1 is an exploded diagrammatic view in axial section of a power module of the prior art;

FIG. 2 is a fragmentary diagrammatic view in section of a power module of the invention;

FIGS. 3 and 3A are fragmentary diagrammatic views in section before and after fastening the package of a power module in a variant of the invention; and

FIG. 4 is a fragmentary diagrammatic view in section showing the fastening of a package of a power module in a variant of the invention.

Reference is made initially to FIG. 1, which shows a power module 10 of the prior art comprising a soleplate 12 of a metal-matrix composite material having a substrate or support 14 of ceramic soldered thereto, the support having two metal-plated faces 16 and 18, one on top and one underneath. Electronic components 20, such as silicon chips, are fastened to the support by soldering. A polymer package 22 is mounted on the support 14 or on the soleplate in order to cover the electronic components 20, and it includes side walls 24 having their ends facing the support 14 and fastened thereto by adhesive joints engaging the support 14.

A heat sink 25 is fastened to the face of the soleplate 12 that is opposite from support 14 in order to dump to the outside the heat that is dissipated inside the package 22 by the electronic components 20.

The enclosure defined by the support 14 and by the package 22 may be filled with a dielectric gel that provides electrical insulation for the components 20 of the power module 10.

When the power module 10 is incorporated in an all-electric actuator for an aircraft, it is subjected to relatively high levels of vibration and acceleration, thereby inducing traction forces on the adhesive joints connecting the package to the support. In order to guarantee that the package 22 is fastened to the support 14 under all circumstances, recourse is had to additional fastening by means of bolting elements, which is not satisfactory because of the resulting increase in weight.

The invention enables this drawback to be remedied by providing fastening between the package 28 and an intermediate part 30 that is mounted inside the package 28 and that is fastened by appropriate means to the support 14, with this being done so as to cause the zone fastening the package 28 to the intermediate part 30 to be stressed in shear and not in traction, and so as to avoid having recourse to additional bolting elements, as in the prior art.

In one embodiment of the invention, as shown in FIGS. 2, 3, and 3A, the side walls 26 of the package 28 are fastened to corresponding faces of the intermediate part 30 by adhesive.

The faces of the intermediate part 30 facing the walls 26 of the package advantageously include surface treatment 32 to promote adhesion in order to improve fastening via the adhesive 33 joint.

As shown in FIG. 2, the side walls 26 of the package 28 and the facing faces of the intermediate part 30 are perpendicular to the support 14.

In this configuration, the package 28 is dimensioned so that its side walls 26 leave a gap relative to the corresponding faces of the intermediate part 30 in order to receive liquid adhesive injected via the side walls of the package and in the corners formed between the side walls 26 of the package 28.

This gap for mounting the package is provided by spacers 34 engaged between the side walls 26 of the package 28 and the faces of the intermediate part 30. These spacers 34 may be formed on the faces of the intermediate part 30 or on the walls 26 of the package 28.

In another embodiment of the invention shown in FIGS. 3 and 3A, the side walls 36 of the package 38 and the faces of the intermediate part 40 are inclined obliquely relative to the support 14, with this angle of inclination being such as to enable the package 38 to be engaged on the intermediate part 40.

The side walls 36 of the package 38 and the faces of the intermediate part 40 converge slightly going away from the support 14 so as to facilitate positioning the package 38 on the intermediate part 40 (FIG. 3A).

In this embodiment, it is possible to use a thixotropic adhesive 41, which becomes spread out while the package 38 is being engaged on the intermediate part 40 (FIG. 3A), thereby avoiding injecting liquid adhesive through the package 28, as in the configuration of FIG. 2.

In the embodiment shown in FIG. 4, the walls 42 of the package 44 and the corresponding faces of the intermediate part 46 are parallel and obliquely inclined relative to the support 14. The side walls 42 of the package 44 are applied directly against the corresponding faces of the intermediate part 46, and the package 44 is fastened by laser welding through the package 44.

This laser welding consists in focusing a laser beam through the package 44, onto the zone of contact between the side walls 42 and the faces of the intermediate part 46. The accumulation of heat in the intermediate part 46 then causes a fine layer of the material of the inside faces of the side walls 42 of the package to melt, and thus enables the package 44 to be welded to the intermediate part 46.

By way of example, the material used for the package is a polymer material. This type of material is transparent to infrared radiation and is therefore well adapted to laser welding by means of an infrared laser beam.

In all of the embodiments of the invention shown in the drawing, the ends of the walls of the intermediate part 30, 40, 46 facing the support 14 include surface treatment 48 for enhancing adhesion on the metal-plated support (shown in FIG. 2). The intermediate part 30, 40, 46 may be fastened to the support by soldering, welding, sintering, or laser welding.

According to the invention, the material selected for the intermediate part 30, 40, 46 depends solely on obtaining good fastening for the package, and when using an adhesive layer for fastening purposes, on the constraints imposed on the utilization of the adhesive.

In another embodiment of the invention, the intermediate part may be a continuous frame mounted around the electronic components 20 and having as many side faces as the package has side walls, thus enabling the package to be fastened to the intermediate part around its entire periphery. Such an intermediate part may thus form a reservoir around the components for receiving the dielectric gel prior to mounting the package, thus making it possible to provide the package as a single piece, unlike the prior art where the package needs to include an independent cover.

In a variant, the frame may include uprights that are sloping or perpendicular relative to the support, with the package being fastened thereto in discontinuous manner.

The invention is not limited to fastening the package on a support 14 that directly carries the electronic components 20. Thus, in other embodiments of the invention, the intermediate part 30, 40, 46 may be fastened on a part such as the soleplate 12.

1. An electronic power module comprising a support having electronic components mounted thereon together with a package covering and surrounding the components and fastened on the support, wherein the package has walls fastened on corresponding faces of an intermediate part that is fastened to the support inside the package, said walls of the package and the corresponding faces of the intermediate part being inclined obliquely on the support of the components.

2. A module according to claim 1, wherein the walls of the package and the corresponding faces of the part are parallel or converge going away from the support.

3. A module according to claim 1, wherein the above-mentioned walls of the package and the corresponding faces of the part are fastened to one another by a layer of adhesive.

4. A module according to claim 3, wherein the adhesive is a thixotropic adhesive.

5. A module according to claim 2, wherein said walls of the package and the corresponding faces of the part are applied against one another and are fastened together by laser welding through the walls of the package.

6. A module according to claim 1, wherein the package is made of a polymer material.

7. A module according to claim 1, wherein the intermediate part is fastened to the support by soldering, welding, sintering, or laser welding.

8. An all-electric actuator, in particular for an aircraft, including an electronic power module according to claim 1.
